(19) United States
(12) Patent Application Publication
(10) Pub. No.: US 2015/0289421 A1
(43) Pub. Date: Oct. 8, 2015

(54) APPARATUS FOR AN EMP SHIELD FOR COMPUTING DEVICES

(71) Applicant: Joel Ho, Saratoga, CA (US)

(72) Inventor: Joel Ho, Saratoga, CA (US)

(21) Appl. No.: 14/746,239

(22) Filed: Jun. 22, 2015

Related U.S. Application Data
(63) Continuation-in-part of application No. 13/923,302, filed on Jun. 20, 2013, now Pat. No. 9,113,550.

(51) Int. Cl. H05K 9/00; H05K 7/20

(52) U.S. Cl. CPC H05K 9/0041; H05K 9/0094; H05K 7/20709; H05K 9/0043; H05K 9/0015

(57) ABSTRACT

An apparatus includes a first electrically conductive mesh material having a transparent material that is configured for venting heat from a computing device. The first electrically conductive mesh material is configured to be flexible for folding to enclose the computing device. The first electrically conductive mesh material is configured for mitigating electro-magnetic pulse damage to the enclosed computing device. A second electrically conductive mesh material has a transparent material that is configured for venting heat from the computing device. The second electrically conductive mesh material is configured to be flexible for folding to enclose the first electrically conductive mesh material. The second electrically conductive mesh material is configured for mitigating electro-magnetic pulse damage to the enclosed computing device. At least one sealing member electrically seals the first electrically conductive mesh material and the second electrically conductive mesh material about the computing device.

### CROSS-REFERENCE TO RELATED APPLICATIONS

The present continuation-in-part patent application claims priority benefit of the U.S. provisional application for patent serial number 61804382, entitled “HIGH-ALTITUDE EMP SHIELD FOR ELECTRONICS”, filed on 22 Mar. 2013, under 35 U.S.C. 119(e), and U.S. patent application Ser. No. 13/923,302 entitled “APPARATUS FOR AN EMP SHIELD FOR PORTABLE DEVICES” filed on 20 Jun. 2013 under 35 USC 111(a), which is hereby incorporated by reference for all purposes to the extent that such subject matter is not inconsistent herewith or limiting hereof.

### RELATED CO-PENDING U.S. PATENT APPLICATIONS

Not applicable.

### FEDERALLY SPONSORED RESEARCH OR DEVELOPMENT

Not applicable.

### REFERENCE TO SEQUENCE LISTING, A TABLE, OR A COMPUTER LISTING APPENDIX

Not applicable.

### COPYRIGHT NOTICE

A portion of the disclosure of this patent document contains material that is subject to copyright protection by the author thereof. The copyright owner has no objection to the facsimile reproduction by anyone of the patent document or patent disclosure for the purposes of referencing as patent prior art, as it appears in the Patent and Trademark Office, patent file or records, but otherwise reserves all copyright rights whatsoever.

### FIELD OF THE INVENTION

One or more embodiments of the invention generally relate to electromagnetic shielding. More particularly, the invention relates to electromagnetic shielding for electrical devices.

### BACKGROUND OF THE INVENTION

The following background information may present examples of specific aspects of the prior art (e.g., without limitation, approaches, facts, or common wisdom) that, while expected to be helpful to further educate the reader as to additional aspects of the prior art, is not to be construed as limiting the present invention, or any embodiments thereof, to anything stated or implied therein or inferred thereupon.

Electromagnetic fields are often generated from a variety of sources ranging from everyday devices to solar flares. Additionally, there exist many different kinds of electromagnetic fields based on the frequency and strength of the electromagnetic radiation associated with an electromagnetic field. Electrical devices may often be sensitive or susceptible to damage caused by electromagnetic fields. Traditional electromagnetic shields for electrical devices often provide varying degrees of electromagnetic field protection by completely enclosing a device in a protective covering and creating a Faraday cage.

Often times, electrical devices are also sensitive to heat and may generate significant amounts of heat during operation. Heat buildup is typically undesirable, with excessive heat potentially damaging electrical devices. Heat dissipation solutions typically involve ensuring proper airflow and/or a having large heat dissipating surface area.

The following is an example of a specific aspect in the prior art that, while expected to be helpful to further educate the reader as to additional aspects of the prior art, is not to be construed as limiting the present invention, or any embodiments thereof, to anything stated or implied therein or inferred thereupon. By way of educational background, another aspect of the prior art generally useful to be aware of is that one existing solution protects an electronic device by placing the electronic device in an electromagnetically shielded bag.

In view of the foregoing, it is clear that these traditional techniques are not perfect and leave room for more optimal approaches.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 illustrates an exemplary method for protecting devices, in accordance with an embodiment of the present invention;

FIG. 2 illustrates an exemplary apparatus for protecting devices, in accordance with an embodiment of the present invention;

FIG. 3 illustrates an exemplary apparatus for protecting devices that allows plugs and other attachments, in accordance with an embodiment of the present invention;

FIG. 4 illustrates an apparatus for protecting devices that incorporates a means of flattening the protective covering, in accordance with an embodiment of the present invention;

FIG. 5 illustrates an apparatus for protecting devices, in accordance with an embodiment of the present invention;

FIG. 6 illustrates an exemplary apparatus for protecting devices that incorporates a wireless relay, in accordance with an embodiment of the present invention;

FIG. 7A illustrates an exemplary apparatus for protecting devices that incorporates touch-typing capability, in accordance with an embodiment of the present invention;

FIG. 7B illustrates an exemplary apparatus for protecting devices, in accordance with an embodiment of the present invention; and

FIG. 8 illustrates an exemplary apparatus for protecting relatively large devices, in accordance with an embodiment of the present invention.

Unless otherwise indicated illustrations in the figures are not necessarily drawn to scale.

### DETAILED DESCRIPTION OF SOME EMBODIMENTS

The present invention is best understood by reference to the detailed figures and description set forth herein.

Embodiments of the invention are discussed below with reference to the Figures. However, those skilled in the art will readily appreciate that the detailed description given herein with respect to these figures is for explanatory purposes as the invention extends beyond these limited embodiments. For example, it should be appreciated that those skilled in the art will, in light of the teachings of the present invention, recognize a multiplicity of alternate and suitable approaches, depending upon the needs of the particular application, to implement the functionality of any given detail described herein, beyond the particular implementation choices in the following embodiments described and shown. That is, there are modifications and variations of the invention that are too numerous to be listed but that all fit within the scope of the invention. Also, singular words should be read as plural and vice versa and masculine as feminine and vice versa, where appropriate, and alternative embodiments do not necessarily imply that the two are mutually exclusive.

It is to be further understood that the present invention is not limited to the particular methodology, compounds, materials, manufacturing techniques, uses, and applications, described herein, as these may vary. It is also to be understood that the terminology used herein is used for the purpose of describing particular embodiments only, and is not intended to limit the scope of the present invention. It must be noted that as used herein and in the appended claims, the singular forms “a,” “an,” and “the” include the plural reference unless the context clearly dictates otherwise. Thus, for example, a reference to “an element” is a reference to one or more elements and includes equivalents thereof known to those skilled in the art. Similarly, for another example, a reference to “a step” or “a means” is a reference to one or more steps or means and may include sub-steps and subservient means. All conjunctions used are to be understood in the most inclusive sense possible. Thus, the word “or” should be understood as having the definition of a logical “or” rather than that of a logical “exclusive or” unless the context clearly necessitates otherwise. Structures described herein are to be understood also to refer to functional equivalents of such structures. Language that may be construed to express approximation should be so understood unless the context clearly dictates otherwise.

All words of approximation as used in the present disclosure and claims should be construed to mean “approximate,” rather than “perfect,” and may accordingly be employed as a meaningful modifier to any other word, specified parameter, quantity, quality, or concept. Words of approximation, include, yet are not limited to terms such as “substantial”, “nearly”, “almost”, “about”, “generally”, “largely”, “essentially”, “closely approximate”, etc.

As will be established in some detail below, is well settle law, as early as 1939, that words of approximation are not indefinite in the claims even when such limits are not defined or specified in the specification.

For example, see Ex parte Mallory, 52 USPQ 297, 297 (Pat. Off. Bd. App. 1941) where the court said “The examiner has held that most of the claims are inaccurate because apparently the laminar film will not be entirely eliminated. The claims specify that the film is “substantially” eliminated and for the intended purpose, it is believed that the slight portion of the film which may remain is negligible. We are of the view, therefore, that the claims may be regarded as sufficiently accurate.”

Note that claims need only “reasonably apprise those skilled in the art” as to their scope to satisfy the definiteness requirement. See Energy Absorption Sys., Inc. v. Roadway Safety Servs., Inc., Civ. App. 96-1264, slip op. at 10 (Fed. Cir. Jul. 3, 1997) (unpublished) Hybridtech v. Monoclonal Antibodies, Inc., 802 F.2d 1367, 1385, 231 USPQ 81, 94 (Fed. Cir. 1986), cert. denied, 480 U.S. 947 (1987). In addition, the use of modifiers in the claim, like “generally” and “substantial,” does not by itself render the claims indefinite. See Seattle Box Co. v. Industrial Crating & Packing, Inc., 731 F.2d 818, 828-29, 221 USPQ 568, 575-76 (Fed. Cir. 1984).

Moreover, the ordinary and customary meaning of terms like “substantially” includes “reasonably close to: nearly, almost, about”, connoting a term of approximation. See In re Frye, Appeal No. 2009-006013, 94 USPQ2d 1072, 1077, 2010 WL 889747 (B.P.A.I. 2010) Depending on its usage, the word “substantially” can denote either language of approximation or language of magnitude. Deering Precision Instruments, L.L.C. v. Vector Distribution Sys., Inc., 347 F.3d 1314, 1323 (Fed. Cir. 2003) (recognizing the “dual ordinary meaning of th[e] term [“substantially”] as connoting a term of approximation or a term of magnitude”). Here, when referring to the “substantially halfway” limitation, the Specification uses the word “approximately” as a substitute for the word “substantially” (Fact 4). (Fact 4). The ordinary meaning of “substantially halfway” is thus reasonably close to or nearly at the midpoint between the forwardmost point of the upper or outsole and the rearwardmost point of the upper or outsole.

Similarly, term ‘substantially’ is well recognize in case law to have the dual ordinary meaning of connoting a term of approximation or a term of magnitude. See Dana Corp. v. American Axle & Manufacturing, Inc., Civ. App. 04-1116, 2004 U.S. App. LEXIS 18265, *13-14 (Fed. Cir. Aug. 27, 2004) (unpublished). The term “substantially” is commonly used by claim drafters to indicate approximation. See Cordis Corp. v. Medtronic AVE Inc., 339 F.3d 1352, 1360 (Fed. Cir. 2003) (“The patents do not set out any numerical standard by which to determine whether the thickness of the wall surface is ‘substantially uniform.’ The term ‘substantially,’ as used in this context, denotes approximation. Thus, the walls must be of largely or approximately uniform thickness.”); see also Deering Precision Instruments, LLC v. Vector Distribution Sys., Inc., 347 F.3d 1314, 1322 (Fed. Cir. 2003); Epcon Gas Sys., Inc. v. Bauer Compressors, Inc., 279 F.3d 1022, 1031 (Fed. Cir. 2002). We find that the term “substantially” was used in just such a manner in the claims of the patents-in-suit: “substantially uniform wall thickness” denotes a wall thickness with approximate uniformity.

It should also be noted that such words of approximation as contemplated in the foregoing clearly limits the scope of claims such as saying ‘generally parallel’ such that the adverb ‘generally’ does not broaden the meaning of parallel. Accordingly, it is well settled that such words of approximation as contemplated in the foregoing (e.g., like the phrase ‘generally parallel’) envisions some amount of deviation from perfection (e.g., not exactly parallel), and that such words of approximation as contemplated in the foregoing are descriptive terms commonly used in patent claims to avoid a strict numerical boundary to the specified parameter. To the extent that the plain language of the claims relying on such words of approximation as contemplated in the foregoing are clear and uncontradicted by anything in the written description herein or the figures thereof, it is improper to rely upon the present written description, the figures, or the prosecution history to add limitations to any of the claim of the present invention with respect to such words of approximation as contemplated in the foregoing. That is, under such circumstances, relying on the written description and prosecution history to reject the ordinary and customary meanings of the words themselves is impermissible. See, for example, Liquid Dynamics Corp. v. Vaughan Co., 355 F.3d 1361, 69 USPQ2d 1595, 1600-01 (Fed. Cir. 2004). The plain language of phrase 2 requires a “substantial helical flow.” The term “substantial” is a meaningful modifier implying “approximate,” rather than “perfect.” In Cordis Corp. v. Medtronic AVE, Inc., 339 F.3d 1352, 1361 (Fed. Cir. 2003), the district court imposed a precise numeric constraint on the term “substantially uniform thickness.” We noted that the proper interpretation of this term was “of largely or approximately uniform thickness” unless something in the prosecution history imposed the “clear and unmistakable disclaimer” needed for narrowing beyond this simple-language interpretation. Id. In Anchor Wall Systems v. Rockwood Retaining Walls, Inc., 340 F.3d 1298, 1311 (Fed. Cir. 2003)” Id. at 1311. Similarly, the plain language of claim 1 requires neither a perfectly helical flow nor a flow that returns precisely to the center after one rotation (a limitation that arises only as a logical consequence of requiring a perfectly helical flow).

The reader should appreciate that case law generally recognizes a dual ordinary meaning of such words of approximation, as contemplated in the foregoing, as connoting a term of approximation or a term of magnitude; e.g., see Deering Precision Instruments, L.L.C. v. Vector Distrib. Sys., Inc., 347 F.3d 1314, 68 USPQ2d 1716, 1721 (Fed. Cir. 2003), cert. denied, 124 S. Ct. 1426 (2004) where the court was asked to construe the meaning of the term “substantially” in a patent claim. Also see Epcon, 279 F.3d at 1031 (“The phrase ‘substantially constant’ denotes language of approximation, while the phrase ‘substantially below’ signifies language of magnitude, i.e., not insubstantial.”). Also, see, e.g., Epcon Gas Sys., Inc. v. Bauer Compressors, Inc., 279 F.3d 1022 (Fed. Cir. 2002) (construing the terms “substantially constant” and “substantially below”); Zodiac Pool Care, Inc. v. Hoffinger Indus., Inc., 206 F.3d 1408 (Fed. Cir. 2000) (construing the term “substantially inward”); York Prods., Inc. v. Cent. Tractor Farm & Family Ctr., 99 F.3d 1568 (Fed. Cir. 1996) (construing the term “substantially the entire height thereof”); Tex. Instruments Inc. v. Cypress Semiconductor Corp., 90 F.3d 1558 (Fed. Cir. 1996) (construing the term “substantially in the common plane”). In conducting their analysis, the court instructed to begin with the ordinary meaning of the claim terms to one of ordinary skill in the art. Prima Tek, 318 F.3d at 1148. Reference to dictionaries and our cases indicates that the term “substantially” has numerous ordinary meanings. As the district court stated, “substantially” can mean “significantly” or “considerably.” The term “substantially” can also mean “largely” or “essentially.” Webster's New 20th Century Dictionary 1817 (1983).

Words of approximation, as contemplated in the foregoing, may also be used in phrases establishing approximate ranges or limits, where the end points are inclusive and approximate, not perfect; e.g., see AK Steel Corp. v. Sollac, 344 F.3d 1234, 68 USPQ2d 1280, 1285 (Fed. Cir. 2003) where it where the court said [W]e conclude that the ordinary meaning of the phrase “up to about 10%” includes the “about 10%” endpoint. As pointed out by AK Steel, when an object of the preposition “up to” is nonnumeric, the most natural meaning is to exclude the object (e.g., painting the wall up to the door). On the other hand, as pointed out by Sollac, when the object is a numerical limit, the normal meaning is to include that upper numerical limit (e.g., counting up to ten, seating capacity for up to seven passengers). Because we have here a numerical limit—“about 10%”—the ordinary meaning is that that endpoint is included.

In the present specification and claims, a goal of employment of such words of approximation, as contemplated in the foregoing, is to avoid a strict numerical boundary to the modified specified parameter, as sanctioned by Pall Corp. v. Micron Separations, Inc., 66 F.3d 1211, 1217, 36 USPQ2d 1225, 1229 (Fed. Cir. 1995) where it states “It is well established that when the term “substantially” serves reasonably to describe the subject matter so that its scope would be understood by persons in the field of the invention, and to distinguish the claimed subject matter from the prior art, it is not indefinite.” Likewise see Verve LLC v. Crane Cams Inc., 311 F.3d 1116, 65 USPQ2d 1051, 1054 (Fed. Cir. 2002). Expressions such as “substantially” are used in patent documents when warranted by the nature of the invention, in order to accommodate the minor variations that may be appropriate to secure the invention. Such usage may well satisfy the charge to “particularly point out and distinctly claim” the invention, 35 U.S.C. §112, and indeed may be necessary in order to provide the inventor with the benefit of his invention. In Andrew Corp. v. Gabriel Elecs. Inc., 847 F.2d 819, 821-22, 6 USPQ2d 2010, 2013 (Fed. Cir. 1988) the court explained that usages such as “substantially equal” and “closely approximate” may serve to describe the invention with precision appropriate to the technology and without intruding on the prior art. The court again explained in Ecolab Inc. v. Envirochem, Inc., 264 F.3d 1358, 1367, 60 USPQ2d 1173, 1179 (Fed. Cir. 2001) that “like the term ‘about,’ the term ‘substantially’ is a descriptive term commonly used in patent claims to ‘avoid a strict numerical boundary to the specified parameter, see Ecolab Inc. v. Envirochem Inc., 264 F.3d 1358, 60 USPQ2d 1173, 1179 (Fed. Cir. 2001) where the court found that the use of the term “substantially” to modify the term “uniform” does not render this phrase so unclear such that there is no means by which to ascertain the claim scope.

Similarly, other courts have noted that like the term “about,” the term “substantially” is a descriptive term commonly used in patent claims to “avoid a strict numerical boundary to the specified parameter.”; e.g., see Pall Corp. v. Micron Seps., 66 F.3d 1211, 1217, 36 USPQ2d 1225, 1229 (Fed. Cir. 1995); see, e.g., Andrew Corp. v. Gabriel Elecs. Inc., 847 F.2d 819, 821-22, 6 USPQ2d 2010, 2013 (Fed. Cir. 1988) (noting that terms such as “approach each other,” “close to,” “substantially equal,” and “closely approximate” are ubiquitously used in patent claims and that such usages, when serving reasonably to describe the claimed subject matter to those of skill in the field of the invention, and to distinguish the claimed subject matter from the prior art, have been accepted in patent examination and upheld by the courts). In this case, “substantially” avoids the strict 100% nonuniformity boundary.

Indeed, the foregoing sanctioning of such words of approximation, as contemplated in the foregoing, has been established as early as 1939, see Ex parte Mallory, 52 USPQ 297, 297 (Pat. Off. Bd. App. 1941) where, for example, the court said “the claims specify that the film is “substantially” eliminated and for the intended purpose, it is believed that the slight portion of the film which may remain is negligible. We are of the view, therefore, that the claims may be regarded as sufficiently accurate.” Similarly, In re Hutchison, 104 F.2d 829, 42 USPQ 90, 93 (C.C.P.A. 1939) the court said “It is realized that “substantial distance” is a relative and somewhat indefinite term, or phrase, but terms and phrases of this character are not uncommon in patents in cases where, according to the art involved, the meaning can be determined with reasonable clearness.”

Hence, for at least the forgoing reason, Applicants submit that it is improper for any examiner to hold as indefinite any claims of the present patent that employ any words of approximation.

Unless defined otherwise, all technical and scientific terms used herein have the same meanings as commonly understood by one of ordinary skill in the art to which this invention belongs. Preferred methods, techniques, devices, and materials are described, although any methods, techniques, devices, or materials similar or equivalent to those described herein may be used in the practice or testing of the present invention. Structures described herein are to be understood also to refer to functional equivalents of such structures. The present invention will now be described in detail with reference to embodiments thereof as illustrated in the accompanying drawings.

From reading the present disclosure, other variations and modifications will be apparent to persons skilled in the art. Such variations and modifications may involve equivalent and other features which are already known in the art, and which may be used instead of or in addition to features already described herein.

Although Claims have been formulated in this Application to particular combinations of features, it should be understood that the scope of the disclosure of the present invention also includes any novel feature or any novel combination of features disclosed herein either explicitly or implicitly or any generalization thereof, whether or not it relates to the same invention as presently claimed in any Claim and whether or not it mitigates any or all of the same technical problems as does the present invention.

Features which are described in the context of separate embodiments may also be provided in combination in a single embodiment. Conversely, various features which are, for brevity, described in the context of a single embodiment, may also be provided separately or in any suitable subcombination. The Applicants hereby give notice that new Claims may be formulated to such features and/or combinations of such features during the prosecution of the present Application or of any further Application derived therefrom.

References to “one embodiment,” “an embodiment,” “example embodiment,” “various embodiments,” “some embodiments,” “embodiments of the invention,” etc., may indicate that the embodiment(s) of the invention so described may include a particular feature, structure, or characteristic, but not every possible embodiment of the invention necessarily includes the particular feature, structure, or characteristic. Further, repeated use of the phrase “in one embodiment,” or “in an exemplary embodiment,” “an embodiment,” do not necessarily refer to the same embodiment, although they may. Moreover, any use of phrases like “embodiments” in connection with “the invention” are never meant to characterize that all embodiments of the invention must include the particular feature, structure, or characteristic, and should instead be understood to mean “at least some embodiments of the invention” includes the stated particular feature, structure, or characteristic.

References to “user”, or any similar term, as used herein, may mean a human or non-human user thereof. Moreover, “user”, or any similar term, as used herein, unless expressly stipulated otherwise, is contemplated to mean users at any stage of the usage process, to include, without limitation, direct user(s), intermediate user(s), indirect user(s), and end user(s). The meaning of “user”, or any similar term, as used herein, should not be otherwise inferred or induced by any pattern(s) of description, embodiments, examples, or referenced prior-art that may (or may not) be provided in the present patent.

References to “end user”, or any similar term, as used herein, is generally intended to mean late stage user(s) as opposed to early stage user(s). Hence, it is contemplated that there may be a multiplicity of different types of “end user” near the end stage of the usage process. Where applicable, especially with respect to distribution channels of embodiments of the invention comprising consumed retail products/services thereof (as opposed to sellers/vendors or Original Equipment Manufacturers), examples of an “end user” may include, without limitation, a “consumer”, “buyer”, “customer”, “purchaser”, “shopper”, “enjoyer”, “viewer”, or individual person or non-human thing benefiting in any way, directly or indirectly, from use of or interaction, with some aspect of the present invention.

In some situations, some embodiments of the present invention may provide beneficial usage to more than one stage or type of usage in the foregoing usage process. In such cases where multiple embodiments targeting various stages of the usage process are described, references to “end user”, or any similar term, as used therein, are generally intended to not include the user that is the furthest removed, in the foregoing usage process, from the final user therein of an embodiment of the present invention.

Where applicable, especially with respect to retail distribution channels of embodiments of the invention, intermediate user(s) may include, without limitation, any individual person or non-human thing benefiting in any way, directly or indirectly, from use of, or interaction with, some aspect of the present invention with respect to selling, vending, Original Equipment Manufacturing, marketing, merchandising, distributing, service providing, and the like thereof.

References to “person”, “individual”, “human”, “a party”, “animal”, “creature”, or any similar term, as used herein, even if the context or particular embodiment implies living user, maker, or participant, it should be understood that such characterizations are sole by way of example, and not limitation, in that it is contemplated that any such usage, making, or participation by a living entity in connection with making, using, and/or participating, in any way, with embodiments of the present invention may be substituted by such similar performed by a suitably configured non-living entity, to include, without limitation, automated machines, robots, humanoids, computational systems, information processing systems, artificially intelligent systems, and the like. It is further contemplated that those skilled in the art will readily recognize the practical situations where such living makers, users, and/or participants with embodiments of the present invention may be in whole, or in part, replaced with such non-living makers, users, and/or participants with embodiments of the present invention. Likewise, when those skilled in the art identify such practical situations where such living makers, users, and/or participants with embodiments of the present invention may be in whole, or in part, replaced with such non-living makers, it will be readily apparent in light of the teachings of the present invention how to adapt the described embodiments to be suitable for such non-living makers, users, and/or participants with embodiments of the present invention. Thus, the invention is thus to also cover all such modifications, equivalents, and alternatives falling within the spirit and scope of such adaptations and modifications, at least in part, for such non-living entities.

Headings provided herein are for convenience and are not to be taken as limiting the disclosure in any way.

The enumerated listing of items does not imply that any or all of the items are mutually exclusive, unless expressly specified otherwise.

It is understood that the use of specific component, device and/or parameter names are for example only and not meant to imply any limitations on the invention. The invention may thus be implemented with different nomenclature/terminology utilized to describe the mechanisms/units/structures/components/devices/parameters herein, without limitation. Each term utilized herein is to be given its broadest interpretation given the context in which that term is utilized.

Terminology. The following paragraphs provide definitions and/or context for terms found in this disclosure (including the appended claims):

“Comprising.” This term is open-ended. As used in the appended claims, this term does not foreclose additional structure or steps. Consider a claim that recites: “A memory controller comprising a system cache . . . ” Such a claim does not foreclose the memory controller from including additional components (e.g., a memory channel unit, a switch).

“Configured To.” Various units, circuits, or other components may be described or claimed as “configured to” perform a task or tasks. In such contexts, “configured to” or “operable for” is used to connote structure by indicating that the mechanisms/units/circuits/components include structure (e.g., circuitry and/or mechanisms) that performs the task or tasks during operation. As such, the mechanisms/unit/circuit/component can be said to be configured to (or be operable) for perform(ing) the task even when the specified mechanisms/unit/circuit/component is not currently operational (e.g., is not on). The mechanisms/units/circuits/components used with the “configured to” or “operable for” language include hardware—for example, mechanisms, structures, electronics, circuits, memory storing program instructions executable to implement the operation, etc. Reciting that a mechanism/unit/circuit/component is “configured to” or “operable for” perform(ing) one or more tasks is expressly intended not to invoke 35 U.S.C. .sctn.112, sixth paragraph, for that mechanism/unit/circuit/component. “Configured to” may also include adapting a manufacturing process to fabricate devices or components that are adapted to implement or perform one or more tasks.

“Based On.” As used herein, this term is used to describe one or more factors that affect a determination. This term does not foreclose additional factors that may affect a determination. That is, a determination may be solely based on those factors or based, at least in part, on those factors. Consider the phrase “determine A based on B.” While B may be a factor that affects the determination of A, such a phrase does not foreclose the determination of A from also being based on C. In other instances, A may be determined based solely on B.

The terms “a”, “an” and “the” mean “one or more”, unless expressly specified otherwise.

Unless otherwise indicated, all numbers expressing conditions, concentrations, dimensions, and so forth used in the specification and claims are to be understood as being modified in all instances by the term “about.” Accordingly, unless indicated to the contrary, the numerical parameters set forth in the following specification and attached claims are approximations that may vary depending at least upon a specific analytical technique.

The term “comprising,” which is synonymous with “including,” “containing,” or “characterized by” is inclusive or open-ended and does not exclude additional, unrecited elements or method steps. “Comprising” is a term of art used in claim language which means that the named claim elements are essential, but other claim elements may be added and still form a construct within the scope of the claim.

As used herein, the phase “consisting of” excludes any element, step, or ingredient not specified in the claim. When the phrase “consists of” (or variations thereof) appears in a clause of the body of a claim, rather than immediately following the preamble, it limits only the element set forth in that clause; other elements are not excluded from the claim as a whole. As used herein, the phase “consisting essentially of” limits the scope of a claim to the specified elements or method steps, plus those that do not materially affect the basis and novel characteristic(s) of the claimed subject matter.

With respect to the terms “comprising,” “consisting of,” and “consisting essentially of,” where one of these three terms is used herein, the presently disclosed and claimed subject matter may include the use of either of the other two terms. Thus in some embodiments not otherwise explicitly recited, any instance of “comprising” may be replaced by “consisting of” or, alternatively, by “consisting essentially of.”

Devices or system modules that are in at least general communication with each other need not be in continuous communication with each other, unless expressly specified otherwise. In addition, devices or system modules that are in at least general communication with each other may communicate directly or indirectly through one or more intermediaries.

A description of an embodiment with several components in communication with each other does not imply that all such components are required. On the contrary a variety of optional components are described to illustrate the wide variety of possible embodiments of the present invention.

As is well known to those skilled in the art many careful considerations and compromises typically must be made when designing for the optimal manufacture of a commercial implementation any system, and in particular, the embodiments of the present invention. A commercial implementation in accordance with the spirit and teachings of the present invention may configured according to the needs of the particular application, whereby any aspect(s), feature(s), function(s), result(s), component(s), approach(es), or step(s) of the teachings related to any described embodiment of the present invention may be suitably omitted, included, adapted, mixed and matched, or improved and/or optimized by those skilled in the art, using their average skills and known techniques, to achieve the desired implementation that addresses the needs of the particular application.

In the following description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still cooperate or interact with each other.

It is to be understood that any exact measurements/dimensions or particular construction materials indicated herein are solely provided as examples of suitable configurations and are not intended to be limiting in any way. Depending on the needs of the particular application, those skilled in the art will readily recognize, in light of the following teachings, a multiplicity of suitable alternative implementation details.

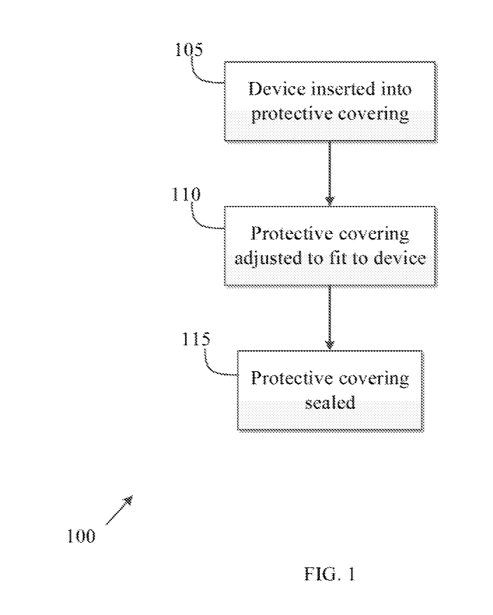

FIG. 1 illustrates an exemplary method for protecting devices, in accordance with an embodiment of the present invention. In the present embodiment, users may insert a device into a protective covering in a step 105. In alternative embodiments, users may fit a protective covering around a device. In other alternative embodiments, users may insert multiple devices into a single protective covering. In still other alternative embodiments, multiple protective coverings may be joined or otherwise used in conjunction to protect one or more devices. In yet other alternative embodiments, users may fit a single protective covering or multiple protective coverings around multiple devices. In the present embodiment, users may adjust the protective covering to fit to one or more electronic devices in a step 110. Users may seal the protective covering in a step 115.

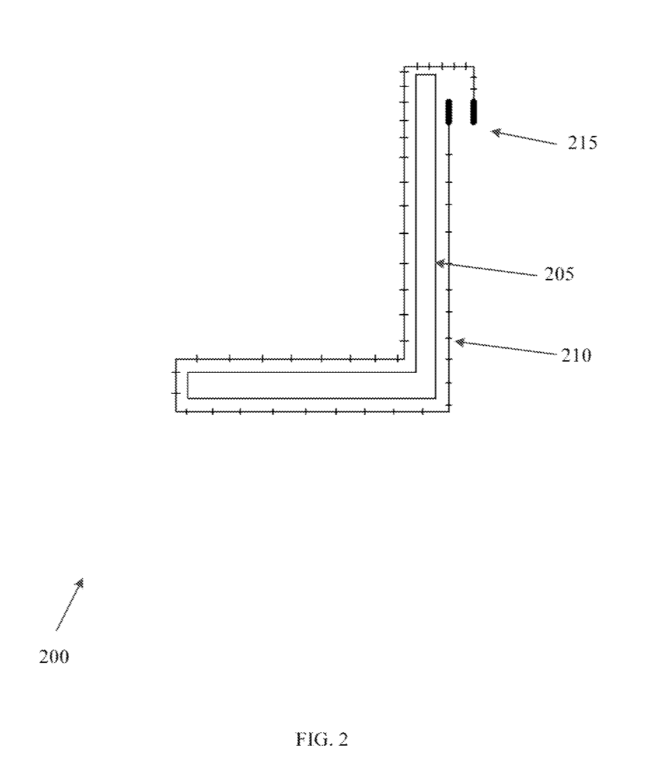

FIG. 2 illustrates an exemplary apparatus for protecting devices, in accordance with an embodiment of the present invention. In the present embodiment, a laptop device 205 may be protected by a protective covering 210. In other embodiments, protected devices may include, without limitation, cell phones, tablets, all-in-one computers, etc. In some embodiments, the protective covering 210 may be composed of a substantially transparent material to allow users to view the protected device 205. In alternative embodiments, the protective covering 210 may be composed of non-transparent materials. In other alternative embodiments, the protective covering 210 may be composed of both transparent and non-transparent materials. In some embodiments, the protective covering 210 may be suitable to protect against electro-magnetic pulses or solar flares. In some of these embodiments, the protective covering 210 may be composed of a conductive material or a combination of multiple conductive materials. In other embodiments, the protective covering may be composed of materials coated/plated by other materials. In a non-limiting example, a protective covering 210 may be substantially composed of stainless steel and coated/plated/electroplated in other materials such as, without limitation, nickel, tin, copper, and/or silver. In alternative embodiments copper mesh may be used. In alternative embodiments, the protective covering 210 may be suitable to protect against other unwanted agents, including, without limitation, heat, cold, particles, fluids, objects, etc. In some embodiments, the protective covering 210 may be designed to allow heat to dissipate through the protective covering 210. In a non-limiting example, the protective covering 210 may be a wire mesh. In the present non-limiting example, the wire mesh may have between 60-120, or approximately 100-105 openings per linear inch ideally to minimize visual distortion. In the present non-limiting example, the mesh is comprised of 105 OPI, Stainless Steel 304 mesh. In other embodiments other mesh types may be suitable. In a non-limiting example, this mesh is cut at a 45 degree angle to prevent Moire pattern effect, and then it is stitched on the sides. At the top and bottoms of the mesh, the mesh is looped around itself and stitched to create a pocket for magnetic strips that then connect to each other. In some embodiments different coated meshes may be stitched together. In alternative embodiments, any number of openings may be suitable. In the present embodiment, the protective covering 210 may have a sealing means 215. In some embodiments, the protective covering may have one opening. In some of these embodiments, a single sealing means 215 may be used. In alternative embodiments, the protective covering 210 may have multiple openings. In some of these alternative embodiments, the protective covering 210 may have multiple sealing means 215. In a non-limiting example, the sealing means 215 may be composed of a magnetic seal. In the present non-limiting example, the magnetic seal 215 may be comprised of magnetic strips attached to the protective covering 210. Magnetic strips and any other sealing means 215 may be attached to the protective covering 210 by means of, without limitation, gluing or sewing. In other embodiments, the sealing means 215 may be comprised of, without limitation, clamps, adhesive tape, magnets used in conjunction with a suitable metal, Velcro, and other magnetic and/or sealing means. In many embodiments, materials used in the sealing means 215 may be reusable. Embodiments of the present invention, provide transparency around a computer screen, flexibility enough to type through it, a seal to stop outside frequencies, a material that blocks electro-magnetic fields/electro-magnetic pulses EMF/EMP, and permeability to allow waste heat to dissipate. Embodiments of the present invention provide solution that is light, inexpensive, and easy to use. Embodiments may also allow wireless signals through the mesh, and reduce a electronic emissions.

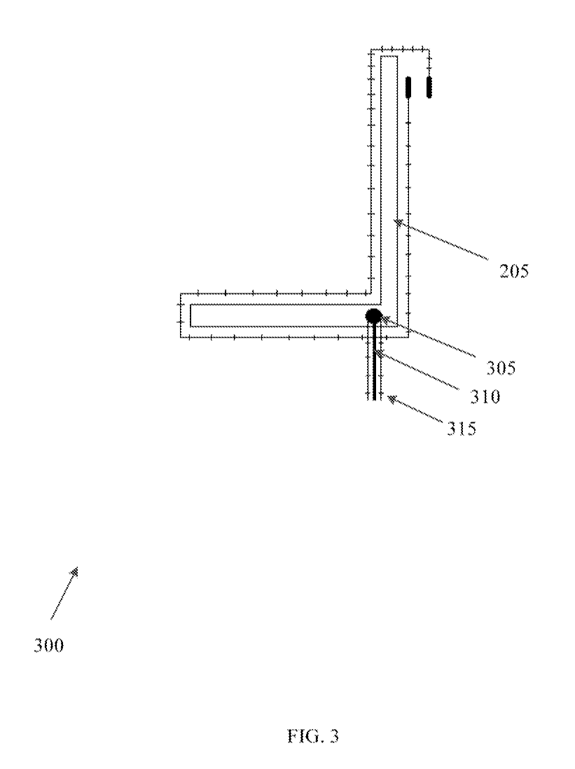

FIG. 3 illustrates an exemplary apparatus for protecting devices that allows plugs and other attachments, in accordance with an embodiment of the present invention. In the present embodiment, a plug 305 with a conductive gasket 310 may be attached to a laptop device 205. The gasket 310 may be a conductive funnel shape that is wider than the diameter of the power cable. The mesh 210 may be glued, taped, or otherwise attached to the funnel. In some embodiments, gasket 310 may have a screw top made of the same material. This allows a screw to be attached to the top and seal the protective covering, or also allow a conductive tube that will contain the power or other cables to be screwed on. The tubing or conductive material may be sized to contain laptop adapters, with a different screw top piece at the end. This may allow the tubing or mesh to be connected to another protected (power) system, with no EMP interference. The protective covering 210 may have suitable openings and/or protective tubing 315 to protect the plug 305 and/or the conductive gasket 310. In other embodiments, the protective covering 210 may have multiple openings to allow other inputs or attachments to the device 205, including, without limitation, wired mouse cables. The protective tubing 315 may be composed of identical material to the protective covering 210 or different materials. The opening and/or protective tubing 315 may be sealed when not in use. In a non-limiting example, the opening and/or protective tubing 315 may be sealed through use of, without limitation, mechanical force, magnetic components, and/or bending.

In some embodiments, the protective covering 210 may be sufficiently flexible to allow manipulation of enclosed devices. In a non-limiting example, a protective covering 210 around a laptop device 205 may be sufficiently flexible to allow a user to type on a keyboard attached to the laptop device 205. In other embodiments, the protective covering 210 may allow users to use wireless devices, such as, without limitation, keyboards and/or mice in conjunction with a device. In many embodiments in which electronic devices may be used, any wireless signals and/or Wi-Fi may be transmitted through the protective covering 210. In some embodiments, the protective covering 210 may be sized to be substantively bigger than a device to be protected. In alternative embodiments, the protective covering 210 may fit tightly on a device.

In other embodiments, the protective covering 210 may stitch to itself to cover any sharp edges. In a non-limiting example, adhesive tape, a fabric border, or any material that is solid enough and can bend around the edges may be used to cover sharp edges of a device.

In still other embodiments, the protective covering 210 may be rotated from a straight orientation to prevent adverse effects. In a non-limiting example in which a laptop device may be used, protective covering material in front of a screen of the laptop device may be rotated 15 to 75 degrees from a straight orientation to either side in order to prevent a Moiré effect. In the present non-limiting example, a rotation of 45 degrees may be a suitable angle to minimize disruption. In other embodiments, the protective covering 210 may be suspended a suitable distance from a screen of a device to prevent the Moiré effect.

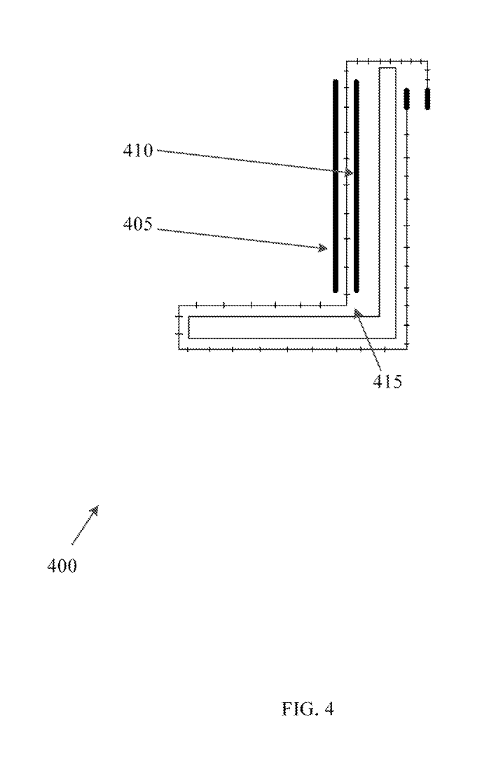

FIG. 4 illustrates an apparatus for protecting devices that incorporates a means of flattening the protective covering, in accordance with an embodiment of the present invention. The flattening means may optionally improve viewing of a screen of device 205. In the present embodiment, a first flattening means 405 may be situated outside the protective covering 210 in relation to the device 205. In some embodiments, the first flattening means 405 may flatten the protective covering 210 against a screen of the device 205. In other embodiments, a second flattening means 410 may be used. The protective covering 210 may be situated between the first flattening means 405 and the second flattening means 410. Flattening means may be attached to the protective covering 210 and/or the device 205 by any fastening means, including, without limitation, glue. In a non-limiting example, flattening means may be an acrylic screen. In at least some embodiments, flattening means may be composed of transparent or near-transparent material. In some embodiments, the second flattening means may be suitable to prevent scratching or other damage to a screen or display of the device 205. In some embodiments, a substantially wide gap 415 between the flattening means 405 and the device 205 may allow users to access components of the device 205. In a non-limiting example in which a laptop device may be used, a gap 415 may allow users to access a keyboard on the laptop device 205.

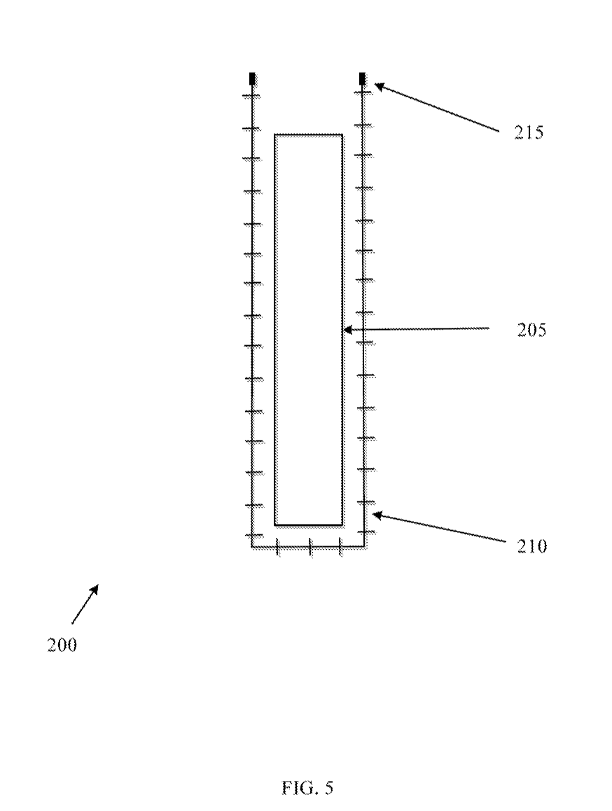

FIG. 5 illustrates an apparatus for protecting devices, in accordance with an embodiment of the present invention. In the present embodiment, a laptop device 205 may be protected by a protective covering 210, and the protective covering 210 may have a sealing means 215, for example without limitation, a magnetic strip. The device in the present embodiment is similar to the device illustrated by way of example in FIG. 2 with the exception of the placement of the sealing means 215. The sealing means 215 in the present embodiment is placed at the top of the enclosure rather than behind the viewing screen. This may optimize the ability for users to place electronic devices within the protecting device that do not “fold” as a laptop typically does such as, but not limited to, tablets.

Some embodiments of the present invention may be suitably lightweight so as to be portable. In some of these embodiments, carrying means may be incorporated to improve portability. Various carrying means may include, without limitation, straps, zippers, or other auxiliary devices. Some embodiments may be folded directly or rolled around a tube-shaped object and carried. Other alternate designs may incorporate a rigid frame like a lattice or metal bar grid in conjunction with the part of the mesh that is in under and behind the electronic device. When folded, the computer's weight would be distributed on the frame. Straps may be attached, if the frame is outside the mesh, directly to the frame.

In some embodiments, shielded ports may be incorporated. In other embodiments, a filtered antenna for use with satellite uplinks may be incorporated. In still other embodiments, a filter may be incorporated to shield for filtering power cable energy. In some embodiments shielded ports and other connections may be done either in the same manner as the power cable was treated above, or, filters may be added. Holes may be cut in the mesh and the filters may be glued onto the mesh. In some embodiments an antenna may be combined to a filter which would be attached, in a similar manner as the power cable connection above.

In other embodiments, the protective covering 210 may be in the form of a containment box with a substantially transparent screen. In a non-limiting example, the containment box may be composed of aluminum or any conductive material and the substantially transparent screen may be composed of metallic mesh.

In still other embodiments, portions of the protective covering may be secured in place by means of a lid stay. In a non-limiting example, a bar may be used to secure a flattening means 405 in place.

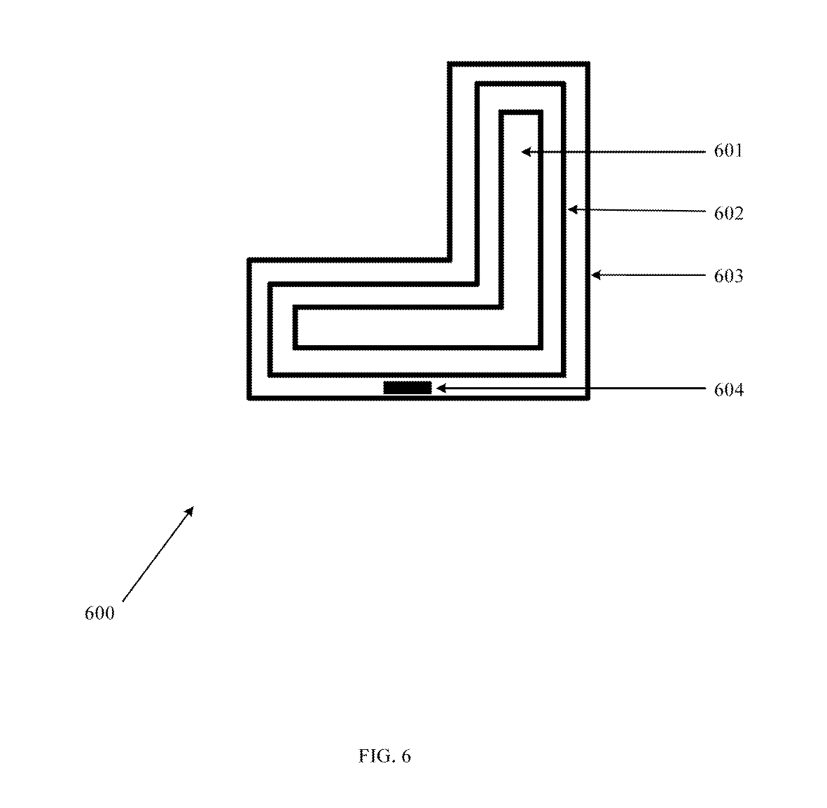

FIG. 6 illustrates an exemplary apparatus for protecting devices that incorporates a wireless relay, in accordance with an embodiment of the present invention. Electromagnetically shielded, wirelessly enabled device 600 comprises of an inner electromagnetic protective layer 602, an outer electromagnetic protective layer 603, and a wireless relay 604. Computing device 601 is placed within inner electromagnetic protective layer 602. Inner electromagnetic protective layer is then placed together with wireless relay 604 within outer electromagnetic protective layer 603.

Inner electromagnetic protective layer 602 and outer electromagnetic protective layer 603 are designed such that neither inner electromagnetic protective layer 602 nor outer electromagnetic protective layer 603 fully block wireless signals that wireless relay 604 will receive. In the present non-limiting example, inner electromagnetic protective layer 602 and outer electromagnetic protective layer 603 are wire meshes that provide electromagnetic protection and do not significantly block airflow. Wireless signals cannot penetrate both inner electromagnetic protective layer 602 and outer electromagnetic protective layer 603.

It may be appreciated to a person with ordinary skill in the art that computing device 601 may be substituted with any device that requires electromagnetic protection. Another embodiment of the present invention may have, but not limited to, computer storage devices, electrical circuits, or sensitive hardware in place of computing device 601.

It may be appreciated to a person with ordinary skill in the art that inner electromagnetic protective layer 602 and outer electromagnetic protective layer 603 need not to be physically identical. Inner electromagnetic protective layer 602 and outer electromagnetic protective layer 603 may be made with different characteristics to be better optimized for specific applications. Another embodiment of the invention may have, but not limited to, an outer electromagnetic protective layer 603 that does not block a large range of electromagnetic frequencies, and an inner electromagnetic protective layer 602 that does not block a narrower range of electromagnetic frequencies. As non-limiting examples, a mesh size of about 250 OPI may block cell phones but may not be transparent, about 100 OPI may block RF and EMP, and two layers may block Bluetooth signals where one layer may only weaken it. Still another embodiment of the invention may have inner electromagnetic protective layer 602 being a metal mesh with specifically sized characteristics such as, but not limited to, mesh count differently than outer electromagnetic protective layer 603 in order to improve heat ventilation while not compromising electromagnetic protection.

It may be appreciated to a person with ordinary skill in the art that there can be a plurality of inner electromagnetic protective layer 602 and outer electromagnetic protective layer 603. Additional electromagnetic protective layers, either physically similar or different, may enclose or be enclosed by inner electromagnetic protective layer 602 or outer electromagnetic protective layer 603 to improve electromagnetic protection. Additional wireless relays similar to wireless relay 604 may be placed between additional electromagnetic protective layers to improve wireless signal strength.

It may be appreciated to a person with ordinary skill in the art that inner electromagnetic protective layer 602 and outer electromagnetic protective layer 603 can be designed to allow certain electromagnetic frequencies pass unblocked or partially blocked. Another embodiment of the present invention may have, but not limited to, an inner electromagnetic protective layer 602 and an outer electromagnetic protective layer 603 that only allows RF frequencies to reach computing device 601.

It may be appreciated to a person with ordinary skill in the art that inner electromagnetic protective layer 602 and outer electromagnetic protective layer 603 may be used to prevent electromagnetic signals from computing device 601 from propagating beyond inner electromagnetic protective layer 602 and/or outer electromagnetic protective layer 603. Another embodiment of the present invention may have, but not limited to, an inner electromagnetic protective layer 602 and/or an outer electromagnetic protective layer 603 that blocks electromagnetic signals originating from computing device 601.

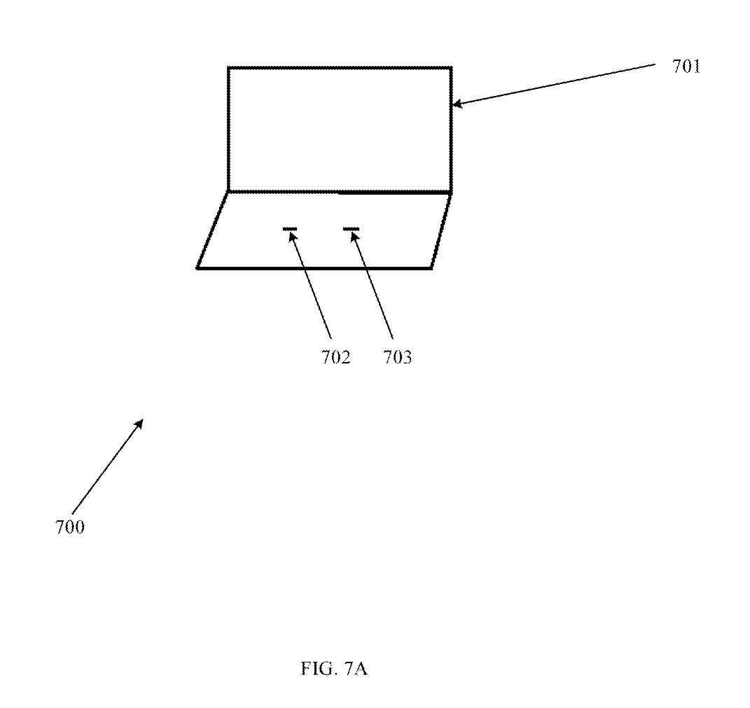

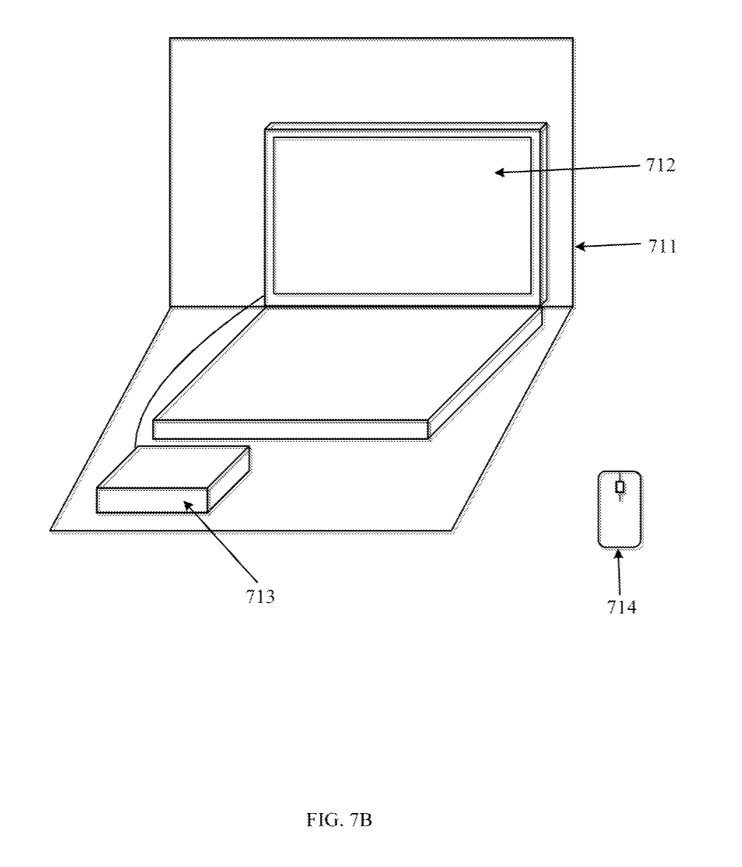

FIG. 7A illustrates an exemplary apparatus for protecting devices that incorporates touch-typing capability, in accordance with an embodiment of the present invention. Electromagnetic shield 700 comprises of an electromagnetic protective layer 701 and keyboard bump 702 and 703. In the present embodiment, electromagnetic protective layer 701 is made from a metal mesh that is mostly transparent and flexible. Keyboard bumps 702 and 703 are physical bumps on electromagnetic protective layer 701 and can be aligned with user selected keys on a keyboard.

It may be appreciated to a person with ordinary skill in the art that keyboard bumps 702 and 703 need not be physical bumps or physically separate bumps. Keyboard bumps 702 and 703 may be replaced with any number of physical designs that may be physically attached, molded, or indented onto electromagnetic protective layer 701. Another embodiment of the present invention may have, but not limited to, electromagnetic protective layer 701 molded with bumps or other designs that can be aligned to specific keys on a keyboard. Still another embodiment of the present invention may have, but not limited to, the outline of the all keys in a typical keyboard indented into electromagnetic protective layer 701.

FIG. 7B illustrates an exemplary apparatus for protecting devices, in accordance with an embodiment of the present invention. Electromagnetic protective layer 711 encloses computing device 712 and recharging device 713. In the present non-limiting example, recharging device 713 powers computing device 712 and removes the need to have external power cables powering computing device 712. User interface device 714 may wirelessly interact with computing device 712.

It may be appreciated to a person with ordinary skill in the art that a plurality of computing devices similar to computing device 712 and/or a plurality of recharging devices similar to recharging device 713 may be placed within electromagnetic protective layer 711. Another embodiment of the present invention may have, but not limited to, a plurality of cellphone devices being powered by recharging device 713.

It may be appreciated to a person with ordinary skill in the art that electromagnetic protective layer 711 may be designed to allow specific wireless frequencies to pass unblocked. Electromagnetic protective layer 711 may be designed with different characteristics such as, but not limited to, copper or stainless steel wire cloth thickness, heat retention, etc. to selectively block certain electromagnetic signals.

It may be appreciated to a person with ordinary skill in the art that electromagnetic protective layer 711 may be designed to allow for optimal operation of computing device 712. Another embodiment of the present invention may have, but not limited to, electromagnetic protective layer 711 being a metal mesh with specifically sized characteristics in order to improve heat ventilation during operation of computing device 712, while not compromising electromagnetic protection.

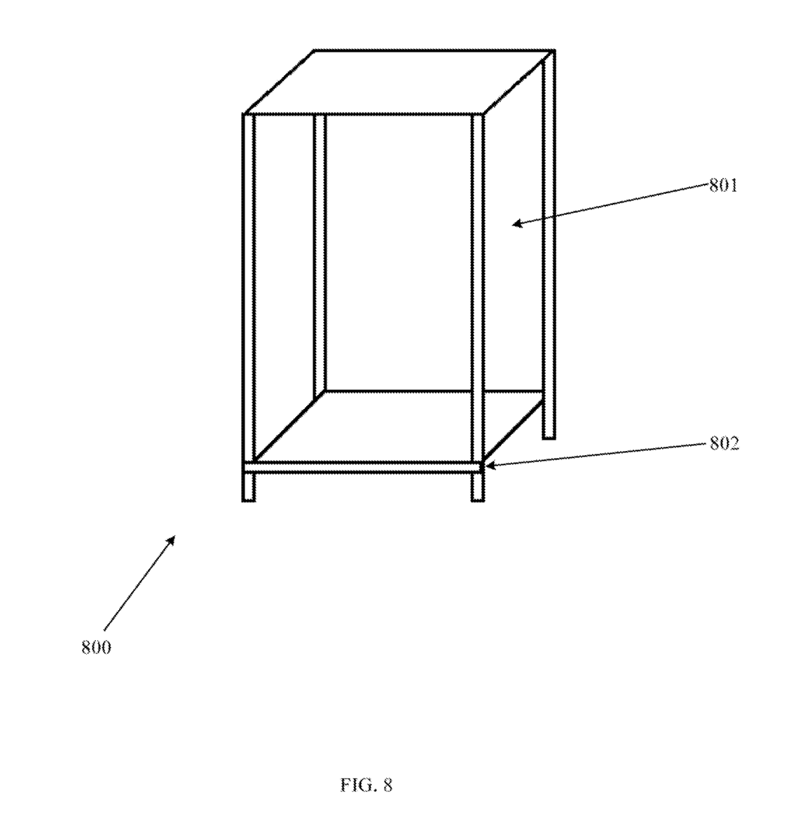

FIG. 8 illustrates an exemplary apparatus for protecting relatively large devices, in accordance with an embodiment of the present invention. Electromagnetically protected server rack 800 comprises of electromagnetic protection layers 801 and server rack frame 802. Electromagnetic protection layers 801 are magnetically attached to server rack frame 802 on all sides of server rack frame 802 including, but not limited to, the top, bottom, front, back, right, and left sides of server rack frame 802. In the present non-limiting example, electromagnetic protection layers 801 are made of a metal mesh that allows for nearly fully unblocked airflow to the inside of server rack frame 802.

It may be appreciated to a person with ordinary skill in the art that electromagnetic protective layers 801 may be designed to allow for optimal operation of any computing machine within server rack frame 802. Another embodiment of the present invention may have, but not limited to, an electromagnetic protective layers 801 being a metal mesh with specifically sized characteristics such as, but not limited to, mesh pattern in order to improve heat ventilation during operation of a computing machine within server rack frame 802, while not compromising electromagnetic protection.

It may be appreciated to a person with ordinary skill in the art that electromagnetic protective layers 801 may be designed to allow specific wireless frequencies to pass unblocked. Electromagnetic protective layers 801 may be designed with different characteristics to selectively block certain electromagnetic signals. Another embodiment of the present invention may have, but not limited to, electromagnetic protective layers 801 designed such that WiFi signals may pass through electromagnetic protective layers 801 and allow communication to any computing device within server rack frame 802.

It may be appreciated to a person with ordinary skill in the art that electromagnetic protective layers 801 may be attached to server rack frame 802 by means other than magnets, such as, but not limited to, Velcro, glue, interlocking pieces, etc. Another embodiment of the present invention may have, but not limited to, electromagnetic protective layers 801 affixed to server rack frame 802 by means of adhesive.

It may be appreciated to a person with ordinary skill in the art that server rack frame 802 may be any type of enclosure. Server rack frame 802 may be, but not limited to, any electronics or containers that may fit inside physically.

Those skilled in the art will readily recognize, in light of and in accordance with the teachings of the present invention, that any of the foregoing steps may be suitably replaced, reordered, removed and additional steps may be inserted depending upon the needs of the particular application. Moreover, the prescribed method steps of the foregoing embodiments may be implemented using any physical and/or hardware system that those skilled in the art will readily know is suitable in light of the foregoing teachings. For any method steps described in the present application that can be carried out on a computing machine, a typical computer system can, when appropriately configured or designed, serve as a computer system in which those aspects of the invention may be embodied.

All the features disclosed in this specification, including any accompanying abstract and drawings, may be replaced by alternative features serving the same, equivalent or similar purpose, unless expressly stated otherwise. Thus, unless expressly stated otherwise, each feature disclosed is one example only of a generic series of equivalent or similar features.

It is noted that according to USA law 35 USC §112 (1), all claims must be supported by sufficient disclosure in the present patent specification, and any material known to those skilled in the art need not be explicitly disclosed. However, 35 USC §112 (6) requires that structures corresponding to functional limitations interpreted under 35 USC §112 (6) must be explicitly disclosed in the patent specification. Moreover, the USPTO's Examination policy of initially treating and searching prior art under the broadest interpretation of a “mean for” claim limitation implies that the broadest initial search on 112(6) functional limitation would have to be conducted to support a legally valid Examination on that USPTO policy for broadest interpretation of “mean for” claims. Accordingly, the USPTO will have discovered a multiplicity of prior art documents including disclosure of specific structures and elements which are suitable to act as corresponding structures to satisfy all functional limitations in the below claims that are interpreted under 35 USC §112 (6) when such corresponding structures are not explicitly disclosed in the foregoing patent specification. Therefore, for any invention element(s)/structure(s) corresponding to functional claim limitation(s), in the below claims interpreted under 35 USC §112 (6), which is/are not explicitly disclosed in the foregoing patent specification, yet do exist in the patent and/or non-patent documents found during the course of USPTO searching, Applicant(s) incorporate all such functionally corresponding structures and related enabling material herein by reference for the purpose of providing explicit structures that implement the functional means claimed. Applicant(s) request(s) that fact finders during any claims construction proceedings and/or examination of patent allowability properly identify and incorporate only the portions of each of these documents discovered during the broadest interpretation search of 35 USC §112 (6) limitation, which exist in at least one of the patent and/or non-patent documents found during the course of normal USPTO searching and or supplied to the USPTO during prosecution. Applicant(s) also incorporate by reference the bibliographic citation information to identify all such documents comprising functionally corresponding structures and related enabling material as listed in any PTO Form-892 or likewise any information disclosure statements (IDS) entered into the present patent application by the USPTO or Applicant(s) or any 3^{rd} parties. Applicant(s) also reserve its right to later amend the present application to explicitly include citations to such documents and/or explicitly include the functionally corresponding structures which were incorporate by reference above.

Thus, for any invention element(s)/structure(s) corresponding to functional claim limitation(s), in the below claims, that are interpreted under 35 USC §112 (6), which is/are not explicitly disclosed in the foregoing patent specification, Applicant(s) have explicitly prescribed which documents and material to include the otherwise missing disclosure, and have prescribed exactly which portions of such patent and/or non-patent documents should be incorporated by such reference for the purpose of satisfying the disclosure requirements of 35 USC §112 (6). Applicant(s) note that all the identified documents above which are incorporated by reference to satisfy 35 USC §112 (6) necessarily have a filing and/or publication date prior to that of the instant application, and thus are valid prior documents to incorporated by reference in the instant application.

Having fully described at least one embodiment of the present invention, other equivalent or alternative methods of implementing electromagnetic shielding for electrical devices according to the present invention will be apparent to those skilled in the art. Various aspects of the invention have been described above by way of illustration, and the specific embodiments disclosed are not intended to limit the invention to the particular forms disclosed. The particular implementation of the electromagnetic shielding for electrical devices may vary depending upon the particular context or application. By way of example, and not limitation, the electromagnetic shielding for electrical devices described in the foregoing were principally directed to consumer electronics and large computing machine implementations; however, similar techniques may instead be applied to room security, medical devices, and communications systems, which implementations of the present invention are contemplated as within the scope of the present invention. The invention is thus to cover all modifications, equivalents, and alternatives falling within the spirit and scope of the following claims. It is to be further understood that not all of the disclosed embodiments in the foregoing specification will necessarily satisfy or achieve each of the objects, advantages, or improvements described in the foregoing specification.

Claim elements and steps herein may have been numbered and/or lettered solely as an aid in readability and understanding. Any such numbering and lettering in itself is not intended to and should not be taken to indicate the ordering of elements and/or steps in the claims.

The corresponding structures, materials, acts, and equivalents of all means or step plus function elements in the claims below are intended to include any structure, material, or act for performing the function in combination with other claimed elements as specifically claimed.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

The Abstract is provided to comply with 37 C.F.R. Section 1.72(b) requiring an abstract that will allow the reader to ascertain the nature and gist of the technical disclosure. It is submitted with the understanding that it will not be used to limit or interpret the scope or meaning of the claims. The following claims are hereby incorporated into the detailed description, with each claim standing on its own as a separate embodiment.

What is claimed is:

1. An apparatus comprising:
a first electrically conductive mesh material comprising a substantially transparent material being configured for venting heat from at least one computing device, said first electrically conductive mesh material further being configured to be flexible for folding to enclose the at least one computing device, said first electrically conductive mesh material further being configured for substantially mitigating electro-magnetic pulse damage to the enclosed at least one computing device and substantially blocking a first group of radio frequencies;
a second electrically conductive mesh material comprising a substantially transparent material being configured for venting heat from the least one computing device, said second electrically conductive mesh material further being configured to be flexible for folding to enclose said first electrically conductive mesh material, said second electrically conductive mesh material further being configured for substantially mitigating electro-magnetic pulse damage to the enclosed at least one computing device and substantially blocking a second group of radio frequencies; and
at least one sealing member being configured for electrically sealing said first electrically conductive mesh material and said second electrically conductive mesh material about the at least one computing device.

2. The apparatus as recited in claim 1, in which said first electrically conductive mesh material and said second electrically conductive mesh material are each cut to angle an orientation of a mesh for substantially mitigating a Moire pattern effect.

3. The apparatus as recited in claim 2, in which said angle is approximately forty five degrees.

4. The apparatus as recited in claim 1, further comprising a wireless relay being dispose between said first electrically conductive mesh material and said second electrically conductive mesh material for strengthening wireless communication with the at least one computing device.

5. The apparatus as recited in claim 1, in which said sealing member comprises a pair of magnetic strips.

6. The apparatus as recited in claim 1, further comprising at least one keyboard bump disposed on at least said second electrically conductive mesh material, said keyboard bump being alignable with a key on a keyboard of the at least one computing device.

7. The apparatus as recited in claim 1, further comprising recharging device being disposed within said first electrically conductive mesh material for powering the at least one computing device.

8. The apparatus as recited in claim 1, in which the at least one computing device comprises one or more servers within a server rack frame.

9. The apparatus as recited in claim 8, in which said at least one sealing member is joinable to the server rack frame.

10. The apparatus as recited in claim 1, in which said at least one sealing member is disposed proximate a top of the at least one computing device.

11. The apparatus as recited in claim 1, in which said first group of radio frequencies and said second group of radio frequencies exclude wireless communication signals.

12. The apparatus as recited in claim 11, in which said wireless communication signals comprise Wi-Fi signals.

13. An apparatus comprising:
means for substantially enclosing at least one computing device for substantially mitigating electro-magnetic pulse damage to the enclosed at least one computing device and substantially blocking a first group of radio frequencies;
means for substantially enclosing said means for enclosing the at least one computing device for substantially mitigating electro-magnetic pulse damage to the enclosed at least one computing device and substantially blocking a second group of radio frequencies; and
means for sealing said means for substantially enclosing said means for enclosing the at least one computing device about the at least one computing device.

14. The apparatus as recited in claim 13, further comprising means for strengthening wireless communication with the at least one computing device.

15. The apparatus as recited in claim 13, further comprising means for aligning with a key on a keyboard of the at least one computing device.

16. The apparatus as recited in claim 13, further comprising means for powering the at least one computing device.

17. An apparatus comprising:
a first electrically conductive mesh material comprising a substantially transparent material being configured for venting heat from at least one computing device, said first electrically conductive mesh material further being configured to be flexible for folding to enclose the at least one computing device, said first electrically conductive mesh material further being configured for substantially mitigating electro-magnetic pulse damage to the enclosed at least one computing device and substantially blocking a first group of radio frequencies in which said first group of radio frequencies excludes wireless communication signals, said first electrically conductive mesh material being cut to angle an orientation of a mesh at approximately forty five degrees for substantially mitigating a Moire pattern effect;
a second electrically conductive mesh material comprising a substantially transparent material being configured for venting heat from the least one computing device, said second electrically conductive mesh material further being configured to be flexible for folding to enclose said first electrically conductive mesh material, said second electrically conductive mesh material further being configured for substantially mitigating electro-magnetic pulse damage to the enclosed at least one computing device and substantially blocking a second group of radio frequencies in which said second group of radio frequencies excludes wireless communication signals, said second electrically conductive mesh material being cut to angle an orientation of a mesh at approximately forty five degrees for substantially mitigating a Moire pattern effect; and
at least a pair of magnetic strips being configured for electrically sealing said first electrically conductive mesh material and said second electrically conductive mesh material about the at least one computing device.

18. The apparatus as recited in claim 17, further comprising a wireless relay being dispose between said first electrically conductive mesh material and said second electrically conductive mesh material for strengthening wireless communication with the at least one computing device.

19. The apparatus as recited in claim 17, further comprising at least one keyboard bump disposed on at least said second electrically conductive mesh material, said keyboard bump being alignable with a key on a keyboard of the at least one computing device.

20. The apparatus as recited in claim 17, further comprising recharging device being disposed within said first electrically conductive mesh material for powering the at least one computing device.
